(19) United States
(12) Patent Application Publication
(10) Pub. No.: US 2025/0185380 A1
(43) Pub. Date: Jun. 5, 2025

(54) PROCESS FOR MAKING CURVED LAMINATED SOLAR PANEL HAVING DECORATIVE APPEARANCE USING DISTORTION PRINTING AND PANEL PRODUCED THEREBY

(71) Applicant: APTERA MOTORS CORP., Carlsbad, CA (US)

(72) Inventor: Anuj M. THAKKAR, Carlsbad, CA (US)

(73) Assignee: APTERA MOTORS CORP., Carlsbad, CA (US)

(21) Appl. No.: 18/843,247

(22) PCT Filed: Mar. 2, 2023
(86) PCT No.: PCT/US23/63600

§ 371 Date: Aug. 31, 2024

Related U.S. Application Data
(60) Provisional application No. 63/315,784, filed on Mar. 2, 2022.

(51) Int. Cl. H10F 19/80; C03B 23/023; H10F 77/14

(52) U.S. Cl. CPC H10F 19/807; H10F 77/147; C03B 23/023

(57) ABSTRACT

The invention relates to an apparatus and method for a curved solar panel with an undistorted printed design. The solar panel comprises a preformed substrate and superstrate having a design printed on at least one surfaces, via distortion printing during preform fabrication. A transformation from a flat state to the curved state is determined. The reverse transformation is applied to the desired design thereby producing a pre-distorted design. The pre-distorted design is printed on a surface of a layer prior to lamination and/or forming. Subsequent lamination may occur. The layer(s) may then be thermoformed into the final preform shape, wherein the design is substantially undistorted. The pre-distorted design may be printed on or proximate to the surface, or may be applied by a back sheet or transfer film and transferred thereto. The preforms are subsequently laminated with encapsulated solar cells forming a curved solar panel with an undistorted design.

### CROSS-REFERENCE TO RELATED APPLICATION

This application claims priority to, and the benefit of, co-pending U.S. Provisional Patent Application No. 63/315,784, filed on Mar. 2, 2022, entitled “Process For Making Curved Laminated Solar Panel Having Decorative Appearance Using Distortion Printing And Panel Produced Thereby”, which is incorporated by reference in its entirety.

### TECHNICAL FIELD

The present invention relates to forming a decorative appearance on a laminate structure and, more particularly, to a process for making a curved laminated solar panel having a decorative appearance using distortion printing.

### BACKGROUND

The forming of a decorative appearance on solar panels presents challenges when adapted to a solar panel having two-axes of curvature, such as, for example, a vehicle or architectural panel having a curved, complex shape. Conventional systems and methods for creating patterns and designs in flat solar panel applications typically employ a transfer sheet, backsheet, or other separately patterned layer. Alternatively, the image may be applied to the solar panel directly. In either case, the pattern may be applied with a suitable printer, such as, for example, a gantry-style printing apparatus. The layer is applied before or after lamination to rigid, flat panels or flexible, planar panels held in a flat state. Imaging on curved surfaces is generally more challenging than on flat surfaces because standard proximity or contact printing techniques, e.g., gantry-style printers, are not capable of handling curved surfaces. As a result, other techniques have been developed.

Illustrative examples of designs or decorations applied to complex surfaces abound in the packaging industry. In one approach, consumable products such as glass and/or plastic bottles can be decorated with heat shrink films. In this technique a pattern, such as a logo or text, is printed on a layer of clear, heat-shrinkable polymer, which is then cut, formed into an open-ended cylinder, placed over the bottle, and heat-shrunk until it conforms to the bottle surface. A layer of adhesive may be used to provide additional durability for the label. In another approach, ink or paint is applied to the surface of a mold in the shape of the item, followed by injection or blow molding of the glass or plastic. The molten plastic bonds to the ink or paint layer forming a highly durable and scratch-resistant design on its surface. In the blister packaging approach, a design or label is printed on a flat layer of clear packaging, followed by shaping of the layer using the blistering technique, resulting in the label positioned on the blister.

In another approach, plastic thermoforming may be used with a printed decoration or label sheet, either laminated or adhered to a sheet of the packaging material. Plastic thermoforming is the broad label given to the manufacturing process that heats thermoplastic sheet material (i.e., “thermos”) and then applies pressure, force, or vacuum to form into a 3-dimensional shape (i.e., “forming”). Methods of thermoforming may include pressure forming, vacuum forming, drape forming, and sag forming, and may depend on the material composition of the item to be formed. In pressure forming, the sheet of thermoplastic material is heated until pliable and placed over a mold. Positive pressure is then applied above the heated sheet, pressing the material into the surface of the mold to create the desired 3-dimensional shape. In vacuum forming, sheet thermoplastic material is heated until pliable and placed over a mold. The air between the heated sheet and mold is then evacuated creating a vacuum that pulls the material onto the surface of the mold to create the desired 3-dimensional shape. One significant difference is that pressure forming allows for pressures greater than one atmosphere to draw a plastic sheet into its final configuration, whereby the additional pressure allows for greater detail and texture when such aesthetics are desired. Drape forming, or sag forming, employs mechanical or manual draping over a mold and may be generally distinguishable in that it does not substantially stretch the plastic during the formation of the part.

These conventional technologies and methods have disadvantages which become apparent when an undistorted image is first printed on a flat sheet and later takes the form of a 3D surface whence it becomes distorted. In cases where this is undesirable, such as lettering, the image may be pre-distorted to counteract this effect. This compensated printing technique is called distortion printing.

In the automotive space, where designs are applied to a variety of vehicles, the most common techniques for applying designs, decorations, or indicia include standard masking and painting, maskless painting (e.g., airbrushing) and adhesive decals. In recent years two other techniques have emerged for applying protective layers and/or designs. Clear bra is a protective film for vehicles that goes by multiple names, such as invisible shield, car scratch protective film, clear mask, etc. A second technique is called a vinyl wrap. Vinyl wraps are made of heavy-duty vinyl that has an adhesive backing on one side. With the addition of polyvinyl chloride (PVC), the vinyl material is significantly strengthened. This gives rise to the excellent durability of car wraps. For flexibility, plasticizers may be used. In the vinyl wrap technique, the film may be applied to individual body panels or an entire vehicle and conforms upon the application of heat or by virtue of adhesives and may be printed or colored. In the above bra and vinyl wrap examples, an image or design is printed first on the flat film and some distortion of the image occurs when it takes the form of the body panel. The clear bra and vinyl wrap films have lifetimes of between 1 and 5 years, depending on exposure, care and maintenance. Yellowing (clear bra) or peeling (clear bra, vinyl wrap) of the of the film are common failure mechanisms. Thus, these techniques, while capable of producing excellent undistorted images on complex surfaces, are not suitable for an automobile panel that is expected to last for many years.

In view of the harsh environment survivability and durability requirements, there is a need for a method for integrating patterns, labels, and designs with a laminated solar body panel of a desired aerodynamic shape having multiple axes of curvature such as, for example, the roof, hood, or trunk of an automobile. In addition, there exists a long-felt need to be able to form a distortion-free, decorative appearance on laminated solar panels, for example, to improve the appearance of the panel.

### SUMMARY

The present invention is directed to an article of manufacture and method for producing a decorative appearance on a curved laminated solar panel using distortion printing, the article of manufacture corresponding to a solar panel produced thereby.

In one aspect of the present invention, a method for producing a decorative appearance is described wherein patterns, labels, and/or designs may be applied to a one-or two-axis of curvature, laminated solar panel, in a manner that allows said patterns, labels, and/or designs to appear substantially undistorted.

In another aspect of the present invention, a one-or two-axis of curvature laminated solar panel is produced that is compatible with the requirements of automotive applications, the solar panel having a distortion-free, decorative appearance.

In another aspect of the present invention, a one-or two-axis of curvature laminated solar panel is produced, the solar panel having a distortion-free, decorative appearance that may be mass produced at low cost. Other desirable features and characteristics will become apparent from the abstract, the detailed description, the drawings, and the claims, when considered in view of this summary.

### DESCRIPTION OF THE DRAWINGS

Non-limiting and non-exhaustive embodiments of the present disclosure are described with reference to the following drawings. In the drawings, like numerals describe like components throughout the several views.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective view of a polymer-based, doubly curved solar panel with doubly curved solar cells, according to an embodiment of the present invention;

FIG. 1B illustrates a detail view of a polymer-based, doubly curved solar panel with doubly curved solar cells, according to an embodiment of the present invention;

FIG. 2A illustrates a perspective view of a glass-based, doubly curved solar panel with doubly curved solar cells, according to an embodiment of the present invention;

FIG. 2B illustrates a detail view of a glass-based, doubly curved solar panel with doubly curved solar cells, according to an embodiment of the present invention;

FIG. 3 illustrates a flowchart of a distortion printing method for a laminated solar panel, according to an embodiment of the present invention;

FIG. 4A illustrates an exploded perspective view of exemplary substrate sheets prior to lamination, employing an inversely-distorted image printed thereon, according to an embodiment of the present invention;

FIG. 4B illustrates a perspective view of exemplary substrate sheets after lamination, employing an inversely-distorted image, according to an embodiment of the present invention;

FIG. 4C illustrates a perspective view of exemplary substrate sheets after thermoforming, employing a distortion-free image, according to an embodiment of the present invention; and

FIG. 5 illustrates a partially-exploded, exemplary lamination stack for a distortion printed, curved laminated solar panel, according to an embodiment of the present invention.

### DETAILED DESCRIPTION

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

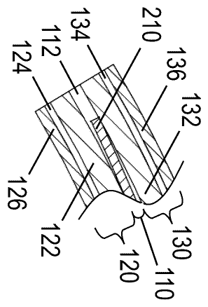

In an embodiment illustrated in FIGS. 1A and 1B, a laminated solar panel 100 comprising a solar cell array 200 encased in a plurality of polymer layers. Referring to FIG. 1A, the solar panel is curved about two axes, X and Y. The curvature may be of the same sign and/or magnitude, as in the figure, or of different sign and/or magnitude. Moreover, the panel may be non-uniformly curved, for example, having more curvature in some portions relative to others. Also, the panel may be singly curved, that is, only about a single axis. A laminated solar panel curved about two axes can be manufactured according to the disclosure of co-pending Non-Provisional patent application Ser. No. 18/169,576, filed on Feb. 15, 2023, entitled Curved Laminated Solar Panel And Method Of Manufacturing Thereof, which claims priority Provisional Patent Application No. 63/310,565, filed on Feb. 15, 2022 entitled Curved Laminated Solar Panel and Method of Manufacture Thereof, both of which are incorporated herein by reference in their entirety. The lamination, shown in the enlarged view of FIG. 1B, includes a plurality of polymer layers which may serve a variety of purposes for the structure and function of the solar panel 100. At the bottom is a substrate 120 which may include one or more polymer layers that provide mechanical stiffness and a seal against water ingress. In one example, the substrate 120 comprises a flexible layer of ethylene tetrafluoroethylene (ETFE) 126, a flexible adhesive layer 124, and a rigid layer of polycarbonate (PC) 122. At the top is a superstrate 130 which includes one or more polymer layers that provide mechanical stiffness, a seal against moisture, and resistance to damage caused by impact. In this embodiment, the superstrate 130 comprises a rigid layer of PC 132, a flexible adhesive layer 134, and a flexible layer of ETFE 136. In general, the PC 122, 132 may be configured to provide mechanical stiffness and impact resistance; while the ETFE 126, 136 acts as a barrier to water ingress, reduces dirt accumulation and provides nick and ding resistance. In the center may be a core 110 comprising the cells 210 of the solar cell array 200 surrounded by a layer of flow-melt adhesive 112, such as polyolefin elastomers (POE) 112. The POE 112 acts as a barrier to water ingress and increases durability and reliability.

As described herein and with respect to any of the embodiments of the disclosure, distortion printing may refer to disposing, or otherwise imparting, a design on or proximate to one or more layers of a lamination stack of which the solar panel is comprised. In this context a design may include an image, label, logo, lettering, or any other indicia. Such designs may be decorative or aesthetically pleasing, or be purposed for masking components from view. A design may comprise a pigment, ink, dye, or other coloring. The design may be disposed on one or more layers of the lamination stack. Where a design is disposed on two or more layers, the design may form a 3D image characterized as having depth or other visual components thereof. In a preferred embodiment, the design may be disposed below the solar cells, in this case on the surfaces, within the layers, or at the interfaces of the substrate 120. For disposing a design in or on the lamination stack, the design may be printed or transferred thereto. In the transferring process, there may be a disposable layer that conveys the design from the printer or location or origin to the layer to be disposed thereto. Among the layers of the embodiment shown and described with respect to FIGS. 1A and 1B, it has been observed that the printing may best be incorporated on the bottom of the ETFE 126 layer. In one aspect, this is preferred because it has been observed that printing on the POE interfacing layers may reduce the adhesion of those POE-adjacent layers. However, printing on any surface within the lamination stack falls within the scope of this disclosure, and the selection of the printing surface is not a limitation thereto.

The polymer layers for the solar panel 100 may be chosen from a large variety of materials. For example, non-limiting alternatives for the PC include glass, polypropylene (PP), polymethyl methacrylate (PMMA), polyethylene terephthalate (PET), polyvinylchloride (PVC), polyethylene (PE), cyclic olefin copolymer (COC), and Fluorinated ethylene propylene (FEP). Non-limiting alternatives for polyolefin (PO), crossing-linking polyolefin (XPO), polyvinyl butyral (PVB), thermoplastic olefin (TPO), ethylene-vinyl acetate (EVA), silicone, polyvinylidene difluoride (PVDF), and thermoplastic polyurethane (TPU). And non-limiting alternatives for the ETFE layers include ethylene chlorotrifluoroethylene (ECTFE).

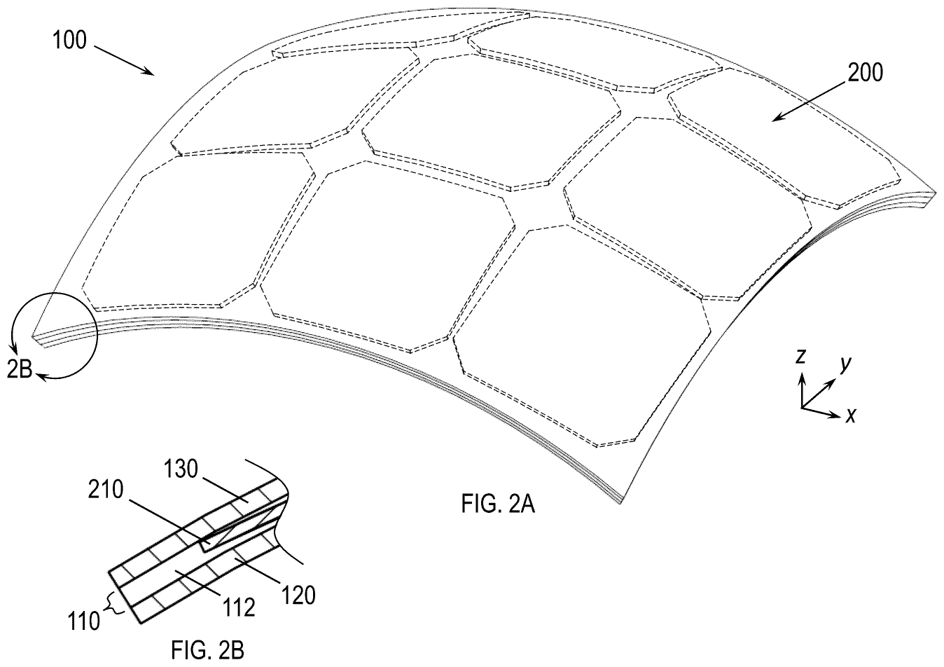

In another embodiment, illustrated in FIGS. 2A and 2B, a laminated solar panel 100 comprises a solar cell array 200 encapsulated in a polymer adhesive 112 and disposed between a pair of preformed, thin, strengthened glass layers 120, 130. The laminate, shown in the detail view of FIG. 2B, includes a pair of glass layers which serve a plurality of purposes for the structure and function of the solar panel 100. At the bottom is a substrate 120 comprised of rigid, ultra-thin, chemically strengthened, alkali-aluminosilicate glass, such as Gorilla® glass from Corning, Dragontail® from Asahi, or Xensation® from Schott, that provides mechanical stiffness. At the top is a superstrate 130 comprised of a rigid layer of ultra-thin, thermally or chemically strengthened glass that provides mechanical stiffness, resistance to impact, resistance to abrasion, and a barrier against moisture. In the center may be a core 110 comprising the cells 210 of the solar cell array 200 surrounded by a layer of flow-melt adhesive, such as POE 112. The POE 112 acts as a barrier to water ingress and increases durability and reliability. In an alternative embodiment, the substrate may be a polymer-based preformed substrate 120 and the superstrate may be a thermally-or chemically-strengthened glass preformed superstrate 130. In another embodiment, the substrate may be a thermally-or chemically-strengthened glass preformed substrate 120 and the superstrate may be a polymer-based preformed superstrate 130.

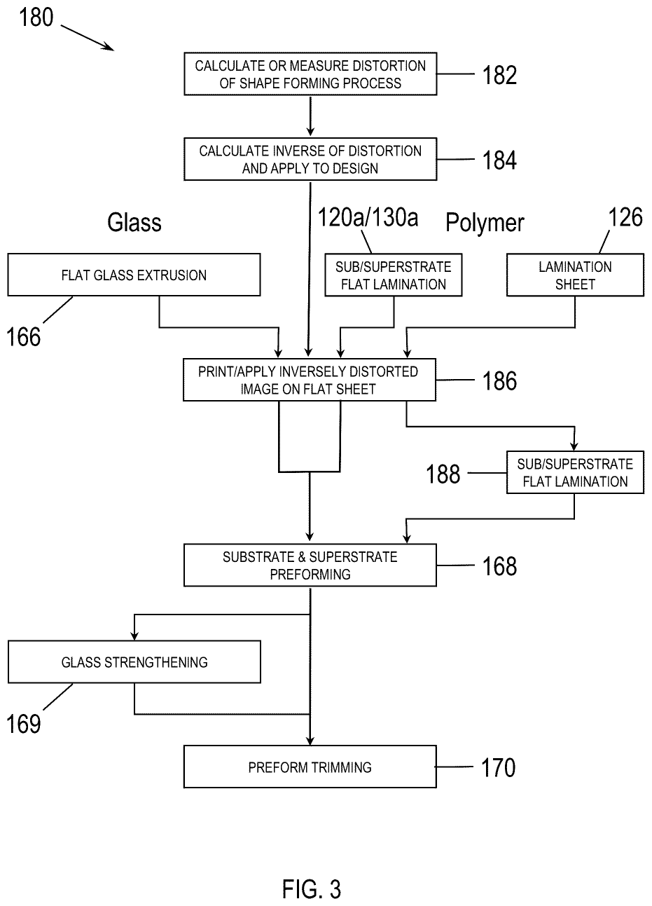

FIG. 3 illustrates a flowchart of the method for distortion printing 180 on a glass or polymer layer or other formable sheet of a laminated solar panel 100 to create the represented printed design when formed. The method 180 may include the following steps. In a first step 182, calculating or measuring the distortion created in a forming process for a design on a solar panel 100 or other component. In a second step 184, calculating the inverse of said distortion and applying it to the desired texture or image to be printed on a flat sheet. Input components for the next step depend on the materials set used. In the case of glass, the as-drawn flat sheet glass 166 is used. For polymers, either a lamination sheet, such as PC 126, or a flat laminated substrate or superstrate 120a, 130a may be used. In a third step 186 the inversely distorted image is either printed (e.g., inks, pigments, etc.) or applied (image sheet, transfer sheet) on a flat sheet to be formed. In the case of a polymer lamination sheet, a fourth step 188 of flat lamination with the other layers of the substrate or superstrate is required. In the next step 168, the flat glass or flat lamination is formed to the final panel shape resulting in the desired image appearing on the surface of the component in the desired proportions. For glass preforms an intermediate step 169 of strengthening, either chemically or thermally, may be performed. In the last step 170, the preforms may be trimmed to the final panel dimensions. The preforms 120 and 130, thusly prepared, may comprise input components to the solar panel lamination process.

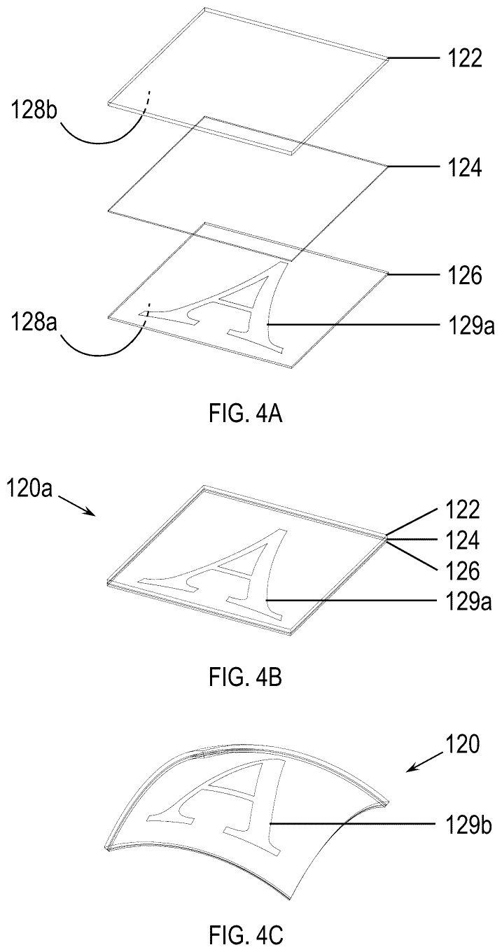

FIGS. 4A-4C illustrate an exemplary embodiment for a process for distortion printing 180 on a polymer layer, or other formable sheet of a laminated solar panel. Referring to FIG. 4A, the inversely distorted image 129a, herein represented as an exemplary letter “A” image, may be printed on a flat laminate surface, such as the bottom surface 128a of the ETFE layer 126. In an alternative embodiment, inversely distorted image 129a may be printed on a bottom surface 128b of the PC layer 122, or on another surface, such as the outer, exposed surface of the superstrate 122, as previously discussed. In an embodiment where the image is printed on the superstrate 122, the image may be registered in a manner such that the solar cells 210 are not blocked or otherwise hidden from solar gain or solar irradiance. In that configuration, the image may selectively hide interconnects, corners of the panel, and/or the like. In another aspect, it may be observed that printing the inversely distorted image 129a prior to any lamination process may be more desirable. For example, printing the inversely distorted image 129a on the ETFE layer 126 first may allow the printed layer to be handled more readily than printing the image 129 on the pre-laminated stack comprising layers 122, 124, and 126, as shown in FIG. 4B. This may be the case if, for example, the ETFE layer 126 is being fed through a printing device. However, printing the inversely distorted image 129a may occur after the flat lamination, corresponding representatively to FIG. 4B.

Referring again to FIG. 4B, the sheets of the substrate 120, i.e., 122, 124, 126, have been laminated together with the image 129a remaining distorted. Lamination may occur using any known method to one skilled in the art. In FIG. 4C the substrate 120 has been thermoformed and the image 129b has been reshaped to the desired proportions. Here, the desired proportions include, for example, a substantially straight appearance of the arms and crossmember forming the letter “A”. The forming may be accomplished via a thermoforming technique, such as, vacuum forming, pressure forming, drape forming, sag forming, or other similar method. Either or both of the substrate 120 and/or superstrate 130 may be printed and/or formed in this or a similar manner.

FIGS. 4A-4C may also describe the process of distortion printing on glass preforms, though the steps are slightly different. In this case, additional lamination layers 122, 124 and the lamination step of FIG. 4B are not used. Referring to FIG. 4A, in a first step the glass 128 is distortion printed 129a in a flat state with an organic or ceramic ink. A screen printer or a digital printer may be used, for example. In the context glass, ceramic inks may be considered the most durable, but their colors are limited. Because ceramics take such a high temperature to fire, their use in polymer applications may be considered as limited. While organic inks may be used in certain applications for glass preforms, due to the upper temperature limit during the curing process, the temperature needed to form the glass tends to cause discoloration or adverse effects of organic inks—whites and yellows in particular. Ceramic inks generally comprise three parts: the colored frit that melts into, e.g., chemically bonds to, the glass; a binder, such as a resin, that holds the frit in place prior to the firing process; and a liquid medium, such as a solvent that allows the ink to be applied.

Drying occurs immediately after the ink is printed. Drying may generally be considered as removing the solvent from the mixture; desirable drying occurs without blistering, cracking, or otherwise over-drying. Generally, passive drying takes too long to be economical. Therefore, active methods of drying of coatings, paints, inks, and the like, can be accomplished with convection heating, infrared energy, a combination of convection and infrared, UV energy, and/or forced-air drying. With convection, the air is heated, transferring energy to the coating. Infrared and UV drying provides highly-efficient electromagnetic energy directly from the heat source to the coating without heating the air therebetween. With forced-air drying, air is passed over the coating and convection occurs. In the context of printing multiple layers directly on top of one another, the presence of binder in the initially-disposed ink may facilitate the adhesion or acceptance of the subsequently-disposed layer. The drying process generally enables a subsequent printing of additional layers.

After drying, a firing may be used, which may generally be considered as removing the binder from the mixture, at which point the frit adheres with and/or to the glass. In one embodiment, firing may occur with the glass in a flat state. The flat glass with adhered frit may then be subjected to preforming 168 and strengthening 169, as in FIG. 3. Alternatively, the firing may occur during the thermoforming process 168. In this way, the glass may then be formed into the desired shape via pressure forming, sag forming, or other known method, as shown in FIG. 4C, with the image 129b then rendered without distortion. Subsequently, the glass may be strengthened, such as by chemical or tempering methods 169.

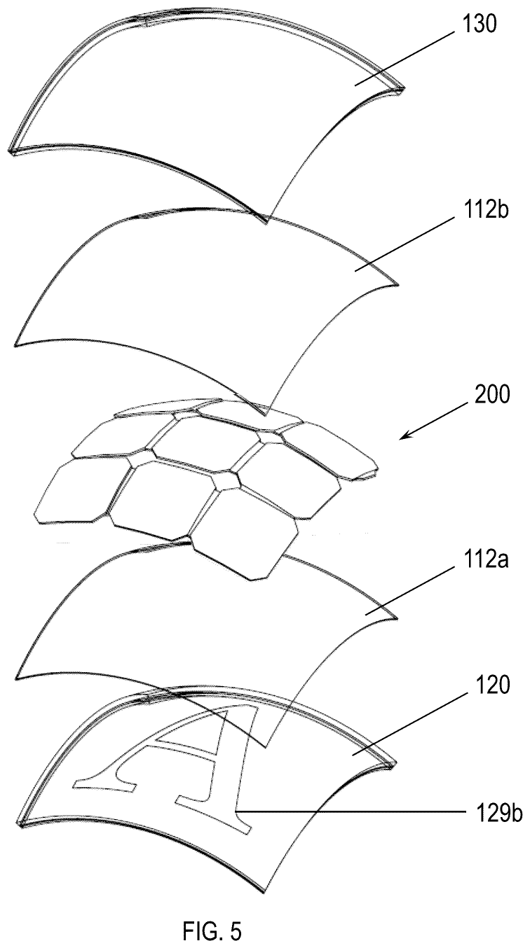

FIG. 5 illustrates the subsequent arrangement of exemplary layers, via an exploded perspective view, that may comprise the laminated solar panel 100. At the bottom is the preformed substrate 120 which may include the distortion-free image 129b. A first encapsulant 112a may be disposed on the substrate 120 followed by placement of the solar cell array 200. A second encapsulant 112b may then be disposed on the solar cell array 200. Then, a preformed superstrate 130, which may be similar in materials and/or construction to the substrate preform 120, may be disposed on the second encapsulant 112b. The lamination stack may then be placed into a laminator and laminated. Note that, with the exception of the solar cell array 200, all of the layers may be fully or partially transparent. Thus, printed surfaces or interfaces above the solar cells may be visible, as well as any printed surfaces or interfaces below and beyond the bounds of the solar cells. If surfaces or interfaces on the superstrate 130 are printed, then to avoid reducing or blocking the light to the cells printing is restricted to in between and/or outside the extents of the cells. Precision alignment between the superstrate 130 and solar cell array 200 may then be relied upon on to avoid overlapping the pattern with the cells.

In an alternative embodiment, other layers in the lamination stack may be printed as desired. For example, one or more laminate layers may be combined to create multi-dimensional images to the laminated solar panel 100 by the lamination process. Graphical effects may be accomplished by using the spatial relationship of the multiple layers such as, for example, depth of view, electroluminescent coatings (i.e., layers that can glow or create illuminated lettering), or other graphical layer combinations. Also, printing on layers above the solar cells 200 can be done for various purposes. For example, it can be used to mask defects, it can be used to mask solar cells 200 from view, or it can be used to create a three-dimensional effect.

In an alternative embodiment, a distortion printed image may be applied to an image sheet or transfer film. This sheet or film is added to the bottom surface 128a of the bottom laminate layer 122 of the substrate 120 as shown in FIGS. 4A and 4B, either before or after flat lamination. The image sheet or transfer film may then remain with the laminated layers through the forming process as, for example, shown in FIG. 4C. If an image sheet is used, it may remain adhered to the finished substrate 120. If a transfer film is used, the transfer film may be removed after the forming step.

While certain configurations of structures have been illustrated for the purposes of presenting the basic structures of the present invention, one of ordinary skill in the art will appreciate that other variations are possible which would still fall within the scope of the appended claims. Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solar panel having one or more axes of curvature, the solar panel comprising:
a substrate and a superstrate each including one or more preformed layers, said substrate and superstrate being preformed in a complementary shape when said solar panel is in an assembled configuration, said substrate characterized by upper and lower substrate surfaces, said superstrate characterized by upper and lower superstrate surfaces;
a core disposed therebetween, said core comprising a solar cell array including at least one solar cell, said solar cell array being encapsulated by one or more encapsulant layers; and
a design disposed proximate one or more of said upper and lower substrate surfaces, and/or proximate said upper and lower superstrate surfaces, said design being formed by a distortion printing process,
wherein in said assembled configuration, said core is integrally formed with said substrate and said superstrate.

2. The solar panel according to claim 1, wherein said design is selected from the group consisting of: an image, a label, a logo, lettering, and/or indicia.

3. The solar panel according to either claim 1 or claim 2, wherein said distortion printing process comprises disposing said design in a flat, distorted orientation prior to preforming said superstrate and/or said substrate, and after preforming, said design is undistorted and exhibits one or more axes of curvature.

4. The solar panel according to any of claims 1 to 3, wherein said design is disposed proximate two or more of said upper and lower substrate surfaces, and/or said upper and lower superstrate surfaces, forming a 3D effect.

5. The solar panel according to any of claims 1 to 4, wherein said one or more preformed layers of said substrate and said superstrate comprise preformed and thermally or chemically strengthened glass.

6. The solar panel according to any of claims 1 to 4, wherein said one or more preformed layers of said substrate and said superstrate comprise polymer-based preformed layers that have been laminated and thermoformed.

7. The solar panel according to any of claims 1 to 6, wherein in said assembled configuration, said core is integrally formed with said substrate and said superstrate such that said at least one solar cell of said solar cell array is curved along two orthogonal axes.

8. The solar panel according to any of claims 1 to 7, further comprising an image sheet, wherein said design is disposed proximate an upper and/or a lower image sheet surface of said image sheet, said image sheet being integrally formed to said lamination stack.

9. The solar panel according to any of claims 1 to 7, further comprising a transfer sheet, wherein said design is conveyed proximate said one or more of said lower substrate surface and/or proximate said upper superstrate surface, said transfer sheet remaining adhered thereto and removed after said preforming process.

10. A method of manufacturing a solar panel having one or more axes of curvature, the method comprising:
determining a transformation required to go from a flat state to a curved state of the solar panel;
applying the reverse of said transformation to form a design characterized by a pre-distorted design;
disposing said pre-distorted design proximate one or more of an upper and a lower substrate surface of a substrate and/or proximate one or more of an upper and a lower superstrate surface of a superstrate;
thermoforming said substrate and said superstrate so that said substrate and said superstrate are each characterized by said curved state which is further characterized by one or more axes of curvature, and so that said substrate and said superstrate form a complementary shape when said solar panel is in an assembled configuration;
disposing a core between said substrate and said superstrate to form a lamination stack, said core comprising a solar cell array including at least one solar cell, said solar cell array being encapsulated by one or more encapsulant layers; and
laminating said lamination stack to form said solar panel wherein said design being undistorted and exhibiting one or more axes of curvature.

11. The method according to claim 10, wherein said disposing said pre-distorted design is a step selected from the group consisting of printing and transferring.

12. The method according to either claim 10 or 11, wherein said design is selected from the group consisting of: an image, a label, a logo, lettering, and/or indicia.

13. The method according to any of claims 10 to 12, wherein said design is disposed on two or more of said upper and lower substrate surfaces, and/or said upper and lower superstrate surfaces, forming a 3D effect.

14. The method according to any of claims 10 to 13, wherein said one or more preformed layers of said substrate and said superstrate comprise preformed and thermally or chemically strengthened glass.

15. The method according to any of claims 10 to 13, wherein said one or more preformed layers of said substrate and said superstrate comprise polymer-based preformed layers that have been laminated and thermoformed.

16. The method according to any of claims 10 to 15, wherein in said assembled configuration, said core is integrally formed with said substrate and said superstrate such that said at least one solar cell of said solar cell array is curved along two orthogonal axes.

17. The method according to any of claims 10 to 16, further comprising the step of providing an image sheet, wherein said design is disposed proximate an upper and/or a lower image sheet surface of said image sheet, said image sheet being integrally formed to said lamination stack.

18. The method according to any of claims 10 to 16, further comprising the step of providing a transfer sheet, wherein said design is conveyed proximate said one or more of said lower substrate surface and/or proximate said upper superstrate surface, said transfer sheet remaining adhered thereto and removed after said preforming process.
